(19) United States
(12) Patent Application Publication
(10) Pub. No.: US 2025/0234607 A1
(43) Pub. Date: Jul. 17, 2025

(54) SEMICONDUCTOR STRUCTURE AND METHOD OF FORMING THE SAME

(71) Applicant: Taiwan Semiconductor Manufacturing Company, Ltd., Hsinchu (TW)

(72) Inventors: I-Hsuan Lo, Hsinchu (TW); Fu-Ting Yen, Hsinchu City (TW); Po-Hsien CHENG, Hsinchu (TW); Hao-Heng Liu, Hsinchu City (TW); Keng-Chu Lin, Ping-Tung (TW)

(73) Assignee: Taiwan Semiconductor Manufacturing Company, Ltd., Hsinchu (TW)

(21) Appl. No.: 18/415,616

(22) Filed: Jan. 17, 2024

(51) Int. Cl. H01L 29/06; H01L 21/768; H01L 21/8234; H01L 27/088; H01L 29/423; H01L 29/66; H01L 29/775; H01L 29/786; H10K 85/40

(52) U.S. Cl. CPC H10D 62/121; H01L 21/76831; H01L 21/76879; H10D 30/014; H10D 30/43; H10D 30/6735; H10D 30/6757; H10D 64/017; H10D 84/0128; H10D 84/013; H10D 84/038; H10D 84/83; H10K 85/40

(57) ABSTRACT

A method for forming a semiconductor structure includes the following steps. A semiconductor device is formed over a substrate. A trench is formed in the semiconductor device. The trench is filled with a gap-fill material using a deposition process, wherein a precursor used in the deposition process includes azidosilane, di-azidosilane or halide azidosilane.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 18 are schematic perspective views and sectional views at various stages in a method of forming a semiconductor structure in accordance with some embodiments of the present disclosure.

FIG. 19 shows schematic cross-sectional views of various steps in a bottom-up a deposition process during the formation of a semiconductor structure in accordance with some embodiments of the present disclosure.

FIG. 20 illustrates a possible reaction mechanism for forming liner structures in the formation of a semiconductor structure in accordance with some embodiments of the present disclosure.

FIG. 21 illustrates a possible reaction mechanism for forming liner structures in the formation of a semiconductor structure in accordance with some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for case of description to describe similar or different element(s) or feature(s) as illustrated in the figures, and may be used interchangeably depending on the order of the presence or the contexts of the description. Source/drain structure(s) may refer to a source or a drain, individually or collectively dependent upon the context.

Although some embodiments described in this disclosure are described in the context of nanosheet channel FETs, implementations of some aspects of the present disclosure may be used in other processes and/or in other devices, such as Horizontal Gate All Around (HGAA) FETs, Vertical Gate All Around (VGAA) FETs, and other suitable devices. A person having ordinary skill in the art will readily understand other modifications that may be made are contemplated within the scope of this disclosure.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

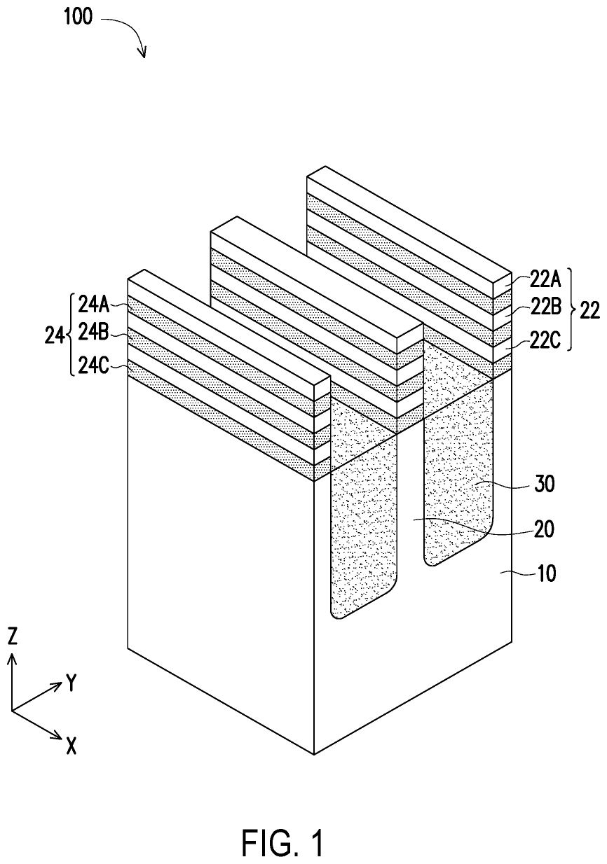

The various aspects of the present disclosure will now be described in more detail with reference to the figures. FIG. 1 through FIG. 18 are schematic perspective views and sectional views at various stages in a method of forming a semiconductor structure 100 in accordance with some embodiments of the present disclosure. It is understood that additional operations can be provided before, during, and after processes shown by FIG. 1 through FIG. 18, and some of the operations described below can be replaced or eliminated, for additional embodiments of the method. The order of the operations/processes may be interchangeable.

Referring to FIG. 1, a substrate 10 is provided. The substrate 10 may be a semiconductor substrate, such as a bulk semiconductor, or the like, which may be doped (e.g., with a p-type or an n-type dopant) or undoped. In some embodiments, the semiconductor material of the substrate 10 includes silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

A multi-layer stack (not shown) including alternating layers of first semiconductor layers and second semiconductor layers may be formed over the substrate 10 and then patterned to form a plurality of nanostructures 22, 24. As shown in FIG. 1, the semiconductor structure 100 may include a front-side and a back-side opposite to the front-side, and the front-side of the semiconductor structure 100 is referred as the side where the nanostructures 22, 24 are formed. In some embodiments, the back-side of the semiconductor structure 100 may also be referred to as “substrate-side”.

In some embodiments, the first semiconductor layers are formed of a first semiconductor material, such as silicon, silicon carbide, or the like, and the second semiconductor layers are formed of a second semiconductor material different from the first semiconductor material, such as silicon germanium, or the like. In some further embodiments, the semiconductor materials of the first semiconductor layers and the second semiconductor layers are selected to have high etch selectivity relative to each other so that either the first or the second semiconductor layers can be removed during subsequent process without significantly removing the other. Each layer of the multi-layer stack may be epitaxially grown using a deposition process, such as a chemical vapor deposition (CVD), an atomic layer deposition (ALD), a vapor phase epitaxy (VPE), a molecular beam epitaxy (MBE), or the like.

Next, the multi-layer stack and the substrate 10 are patterned by one or more photolithography processes (e.g., double-patterning or multi-patterning processes) and a subsequent anisotropic etching process to form the fins 20 within the substrate 10 and the nanostructures 22, 24 over the substrate 10. The etching process may include a reactive ion etch (RIE), a neutral beam etch (NBE), the like, or a combination thereof. For example, first nanostructures 22A-22C (also referred to as “channels” below) are formed from the first semiconductor layers, and second nanostructures 24A-24C are formed from the second semiconductor layers. In some embodiments, the nanostructures 22, 24 are formed to extend along a first direction (e.g., X-direction) and to be arranged in parallel to one another in a second direction (e.g., Y-direction) perpendicular to the first direction. In some further embodiments, nanostructures 22, 24 are patterned to have rectangular cross-sectional shapes having substantially vertical sidewalls. However, it is understood that the nanostructures 22, 24 may include tapered sidewalls.

Isolation regions 30, which may be shallow trench isolation (STI) regions, are formed between adjacent fins 20. In some embodiments, the isolation regions 30 are formed by depositing an insulation material, such as oxide and/or nitride, over the substrate 10, the fins 20, and the nanostructures 22, 24. The deposition of the insulation material may include using a high-density plasma CVD (HDP-CVD) process, a flowable CVD (FCVD) process, the like, or a combination thereof. The insulation material is then planarized and recessed to form the isolation regions 30. In some embodiments, the planarization is performed using a chemical mechanical polish (CMP) process and/or an etch back process, and the recessing of the insulation material is performed using an acceptable etching process, such as an oxide removal process using diluted hydrofluoric acid (dHF). After the recessing step, the nanostructures 22, 24 and upper portions of the fins 20 may protrude from adjacent isolation regions 30 as shown in FIG. 1. The isolation regions 30 may include top surfaces that are flat as illustrated. Alternatively, top surfaces of the isolation regions 30 may be convex, concave, or a combination thereof.

In some further embodiments, appropriate wells (not shown) may be formed in the fins 20, the nanostructures 22, 24, and/or the isolation regions 30. For example, an n-type impurity implantation is performed in p-type regions of the substrate 10, and a p-type impurity implantation is performed in n-type regions of the substrate 10. An annealing process may be performed after the implantations to repair implant damage and to activate the p-type and/or n-type impurities.

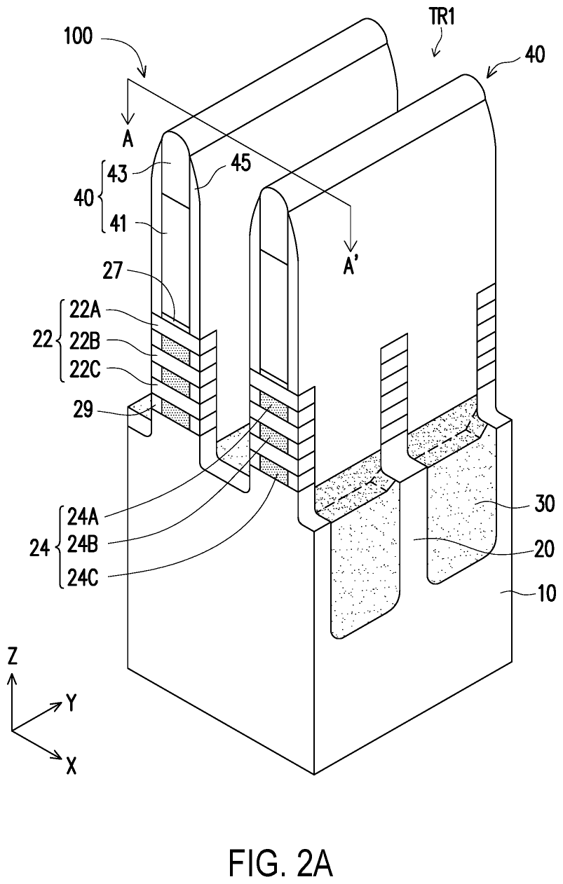

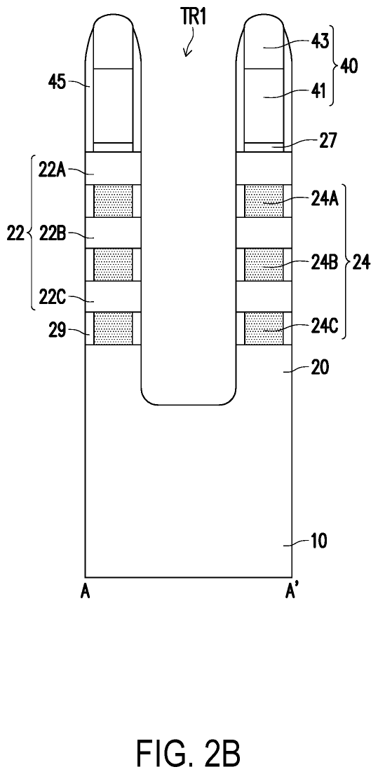

Referring to FIG. 2A, and referring to a cross-sectional view of FIG. 2A taken along the line A-A′ as shown in FIG. 2B, a dielectric layer 27 is formed over the nanostructures 22, 24 and the isolation regions 30, and a plurality of dummy gate structures 40 are formed on the dielectric layer 27 over the nanostructures 22, 24. Each dummy gate structure 40 may include a dummy gate layer 41 and a mask layer 43 over the dummy gate layer 41.

For example, the dielectric layer 27 is formed using a suitable deposition technique (such as a CVD process, a sub-atmospheric CVD (SACVD) process, an ALD process) to conformally cover exposed surfaces of the nanostructures 22, 24 and the isolation regions 30. In some embodiments, the dielectric layer 27 includes silicon oxide, silicon nitride, high-K dielectric material and/or other suitable material.

Thereafter, a dummy gate material layer is deposited on the dielectric layer 27 over the nanostructures 22, 24 and the isolation regions 30. The dummy gate material layer may include conductive, semi-conductive, or non-conductive material. For example, the dummy gate material layer includes amorphous silicon, polycrystalline-silicon (polysilicon), poly-crystalline silicon-germanium (poly-SiGe), metallic nitrides, metallic silicides, metallic oxides, or metals. A mask material layer may be formed over the dummy gate material layer, and may include silicon nitride, silicon oxynitride, or the like. In some embodiments, the dummy gate material layer and the mask material layer are formed by physical vapor deposition (PVD), CVD, sputter deposition, or other suitable techniques.

In accordance with some embodiments, the dummy gate material layer and the mask material layer are then patterned to form a plurality of discrete (i.e., separate) dummy gate structures 40 each including the dummy gate layer 41 and the mask layer 43. In some embodiments, the dummy gate structures 40 are formed to extend along the second direction (e.g., Y-direction) and to be arranged in parallel to one another in the first direction (e.g., X-direction). Subsequently, spacers 45 may be formed on sidewalls of each dummy gate structure 40 (i.e., sidewalls of the dummy gate layer 41 and the mask layer 43). The spacers 45 are, for example, made of an insulation material, such as silicon nitride, silicon oxide, silicon carbo-nitride, silicon oxynitride, silicon oxy carbo-nitride, or the like. The spacers 45 may be formed by depositing a spacer material layer (not shown) over the dummy gate structures 40. Portions of the spacer material layer are removed using an anisotropic etching process, leaving the spacers 45 on sidewalls of each dummy gate structure 40, in accordance with some embodiments.

Still referring to FIG. 2A and FIG. 2B, an etching process is performed to etch the portions of protruding fins 20 and/or nanostructures 22, 24 that are not covered by dummy gate structures 40 and the spacers 45 to form trenches TR1, and a selective etching process is then performed to recess end portions of the nanostructures 24 to further form inner spacers 29 in the recesses (not shown). In some embodiments, the etching process is anisotropic, such that the portions of fins 20 directly under the dummy gate structures 40 and the spacers 45 are protected from being etched. In addition, the etching process may also etch away an upper portion of the isolation regions 30 to form the trenches TR1.

In some embodiments, a suitable dielectric material such as silicon nitride (SiN), silicon oxycarbide (SiOC), silicon carbon nitride (SiCN), silicon oxycarbonitride (SiOCN) is deposited to fill the recesses aside the nanostructures 24 after the selective etching process. For example, a suitable deposition technique such as PVD, CVD, ALD, or the like is used to deposit an inner spacer layer, and then an anisotropic etching process is performed to remove portions of the inner spacer layer outside the recesses. The remaining portions of the inner spacer layer (e.g., portions disposed inside the recesses) form the inner spacers 29, for example. As shown in FIG. 2A and FIG. 2B, outer sidewalls of the inner spacers 29 may be substantially leveled with outer sidewalls of the nanostructures 22 and outer sidewalls of the spacers 45.

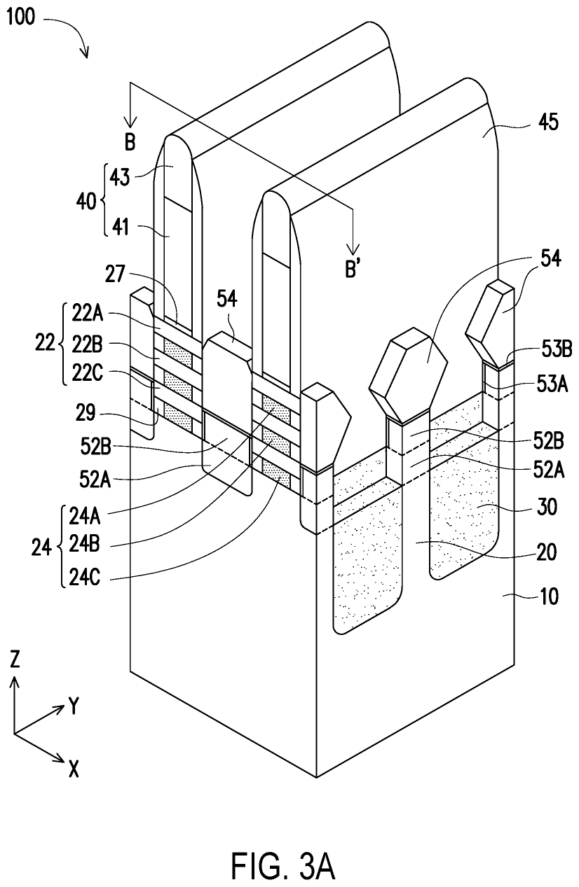

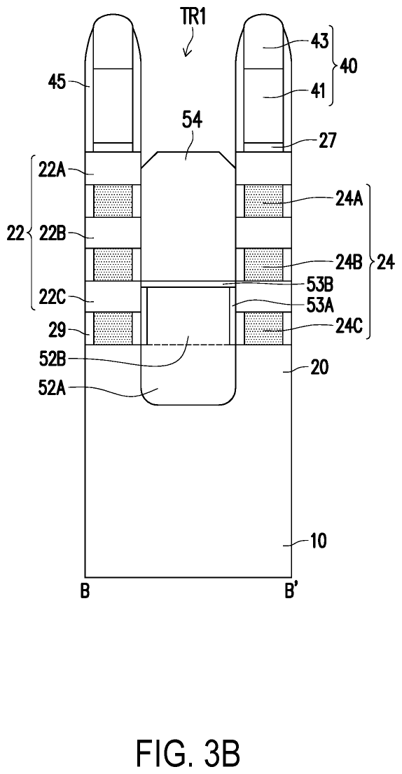

Referring to FIG. 3A, and referring to a cross-sectional view of FIG. 3A taken along the line B-B′ as shown in FIG. 3B, elevated epitaxial structures (including 52A, 52B), liner structures 53A and dielectric layers 53B are formed in the trenches TR1. For example, a first portion 52A of the elevated epitaxial structures are formed in the trenches TR1 so that it is substantially leveled with a bottom surface of the nanostructures 24C. Thereafter, a liner layer (not shown) is conformally formed in the trenches TR1 over the first portion 52A, and a second portion 52B of the elevated epitaxial structures are formed in between the liner layer, whereby the liner layer is etched to form liner structures 53A that partially cover sidewalls of the nanostructures 22, 24. Furthermore, tops of the liner structures 53A are aligned with tops of the second portion 52B of the elevated epitaxial structures. Subsequently, dielectric layers 53B may be formed to cover tops of the liner structures 53A and tops of the second portion 52B.

In some embodiments, the elevated epitaxial structures (including the first portion 52A, and second portion 52B) include Si, Ge, SiGe, the like, or a combination thereof. In some embodiments, the elevated epitaxial structures (including the first portion 52A, and second portion 52B) are formed by an epitaxial growth process and are grown from the bottoms of the trenches TR1. In some embodiments, the liner structures 53A and the dielectric layers 53B cover the second portion 52B, and may prevent contact between source/drain structures formed in subsequent steps, with the channel material of the semiconductor structure 100 or of nanosheets which are not used as active channels.

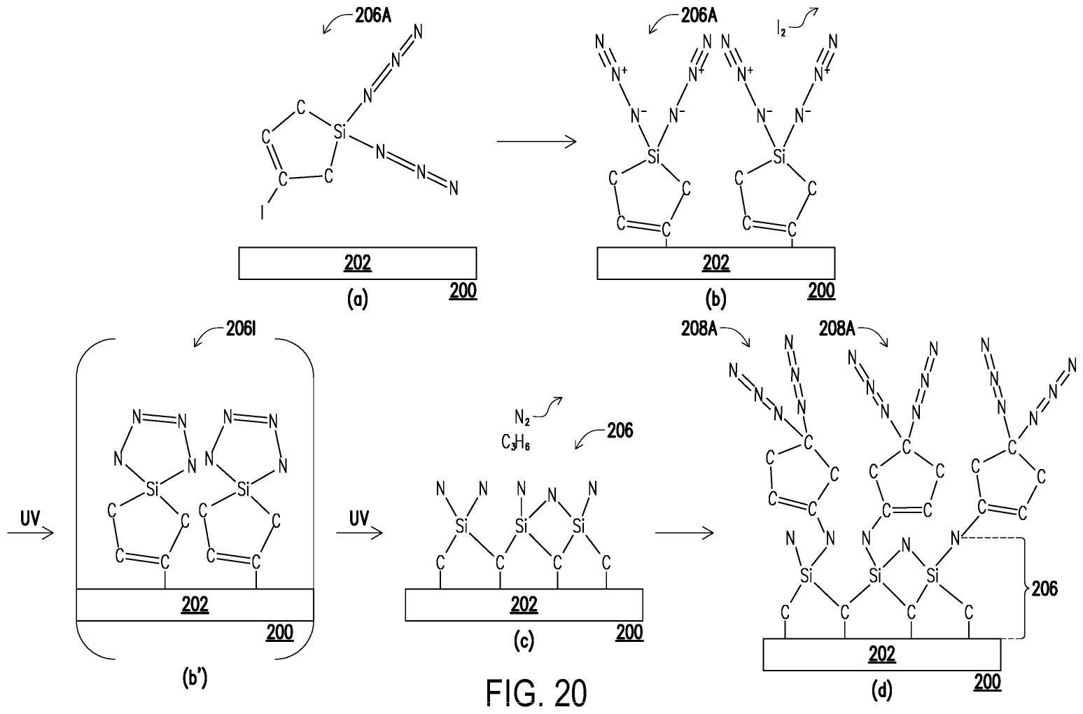

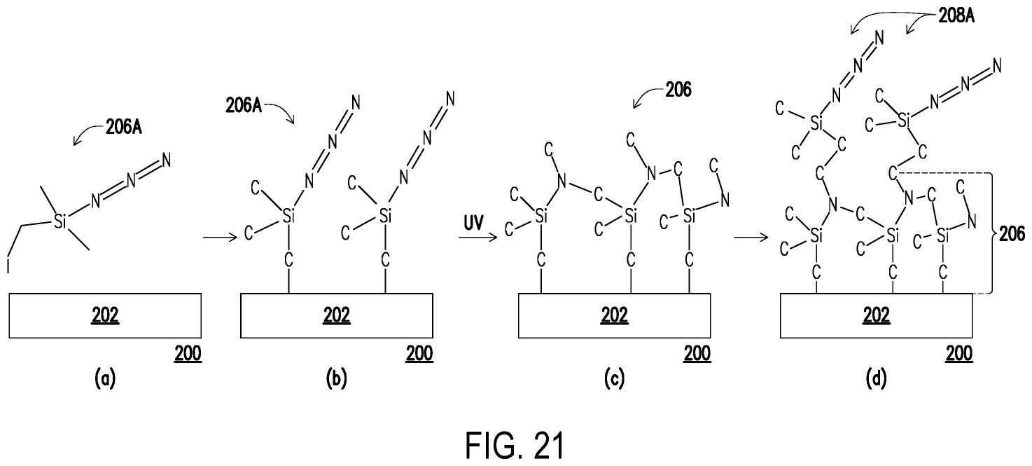

In some embodiments, the liner structures 53A are formed through a deposition process, such as an atomic layer deposition (ALD) process on sidewalls of the trenches TR1, whereby a material and process of forming the liner structures 53A will be described later with reference to FIG. 20 through FIG. 21. By using the material and process of the present disclosure for forming the liner structures 53A, an ultrathin liner structure (<2 nm) that is free of pin-holes or seams can be obtained.

In some embodiments, the dielectric layer 53B may be formed of oxides, such as silicon oxide (SiO), aluminum oxide (AlO), zirconium oxide (ZrO), hafnium oxide (HfO), titanium oxide (TiO), zirconium aluminum oxide (ZrAlO), zinc oxide (ZnO); nitrides, such as silicon nitride (SiN); oxynitrides, such as aluminum oxynitride (AlON); SiCN, SiOCN; or the like. The dielectric layer 53B may be formed by CVD, plasma-enhanced CVD (PECVD), ALD, or any suitable deposition technique. The dielectric layer 53B may be referred to as a coverage dielectric layer or a buffer layer.

In some embodiments, after forming the dielectric layer 53B, source/drain structures 54 are formed on the dielectric layer 53B over the elevated epitaxial structures (including 52A, 52B). In some embodiments, the source/drain structures 54 are formed by an epitaxial growth process and include an angled, curved or irregular profile. For example, the source/drain structures 54 are illustrated with a hexagonal-shaped profile in FIG. 3A and FIG. 3B. The source/drain structures 54 may exert stress in the respective channels 22A-22C, thereby improving the performance of the transistor(s). Each dummy gate structure 40 is sandwiched between a corresponding pair of the source/drain structures 54. In addition, the spacers 45 separate the source/drain structures 54 from the dummy gate layer 41 with an appropriate lateral distance to prevent electrical bridging between the source/drain structures 54 and subsequently formed metal gate structures, for example.

In some embodiments, the source/drain structures 54 may include any acceptable material, for example, appropriate for n-type or p-type devices. For n-type devices, the source/drain structures 54 may include materials exerting a tensile strain in the channel regions, such as silicon, SiC, SiCP, SiP, or the like. For P-type devices, the source/drain structures 54 include materials exerting a compressive strain in the channel regions, such as SiGe, SiGeB, Ge, GeSn, or the like, according to some embodiments. Alternatively, adjacent source/drain structures 54 may merge to form a singular source/drain region alongside two or more adjacent nanostructures 22, 24. Furthermore, in some embodiments, the source/drain structures 54 are implanted with dopants and then undergo an annealing process. In some embodiments, the source/drain structures 54 are in-situ doped during growth.

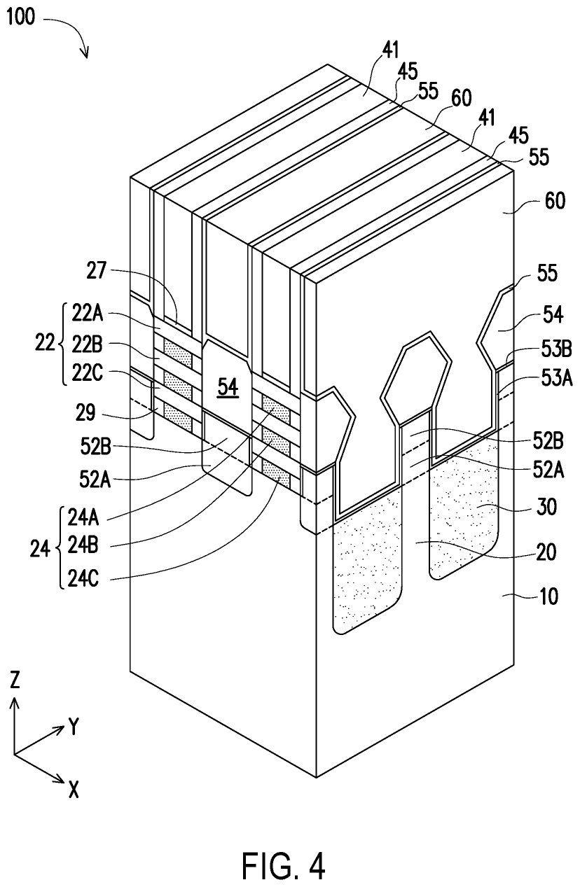

Referring to FIG. 4, in some embodiments, a contact etch stop layer (CESL) 55 and an interlayer dielectric (ILD) layer 60 are sequentially formed to cover the dummy gate structures 40 and the source/drain structures 54. For example, the CESL 55 is conformally formed on the exposed surfaces of the semiconductor structure 100 shown in FIG. 3A and FIG. 3B. In some embodiments, the CESL 55 includes an oxygen-containing material such as silicon oxide and silicon carbon oxide, or a nitrogen-containing material such as silicon nitride, silicon carbon nitride, silicon oxynitride and carbon nitride, or a combination thereof. In some embodiments, the CESL 55 is formed by CVD, PECVD, ALD, or any suitable deposition technique.

As illustrated in FIG. 4, after forming the CESL 55, the ILD layer 60 is then formed on the CESL 55, such that the spaces between the dummy gate structures 40 are filled by the ILD layer 60. In some embodiments, the materials for the ILD layer 60 include compounds comprising Si, O, C, and/or H, such as silicon oxide, tetraethoxysilane (TEOS) oxide, SiCOH and SiOC. Organic materials, such as polymers, may also be used for the ILD layer 60. The ILD layer 60 may be deposited by PECVD, FCVD, or other suitable deposition technique. In some embodiments, after the formation of the ILD layer 60, the semiconductor structure 100 is subject to a thermal process to anneal the ILD layer 60. Further, a planarization process, such as a CMP process, may be performed from the front-side of the semiconductor structure 100 until the dummy gate layers 41 are exposed. For example, the mask layer 43 is entirely removed during the planarization process. In some embodiments, top surfaces of the dummy gate layers 41, the spacers 45, the ILD layer 60 and the CESL 55 are substantially coplanar with one another after the planarization process.

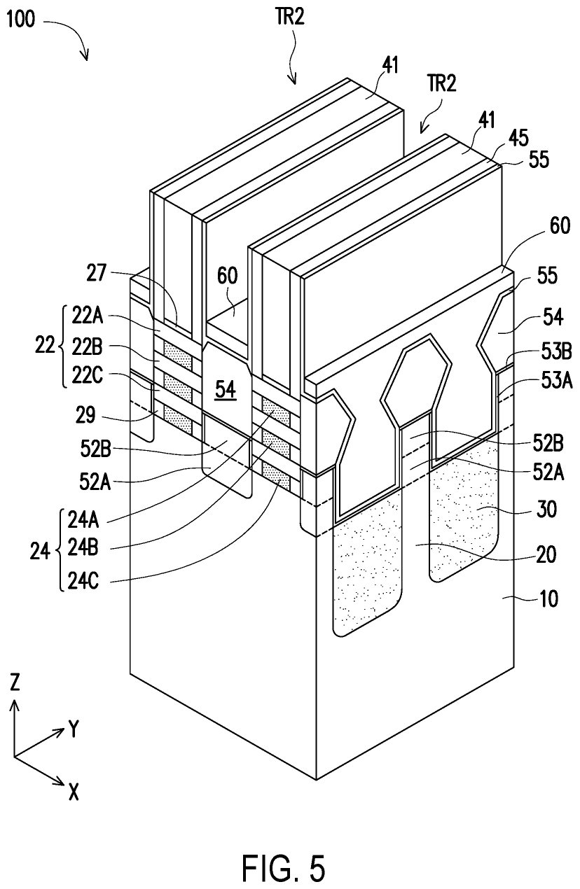

Referring to FIG. 5, in some embodiments, the ILD layer 60 is recessed, thereby forming trenches TR2. For example, an anisotropic etching process such as an etch back process is performed to partially remove the ILD layer 60. In one embodiment, the ILD layer 60 is etched back with a depth less than 100 nm. In some embodiments, a depth to width aspect ratio of the trench TR2 is 3 or more. In other words, the formed trenches TR2 are, for example, high aspect ratio openings. In certain embodiments, a width of the trench TR2 is in a range of 3 nm to 150 nm, and a depth of the trench TR2 is in a range of 15 nm to 300 nm.

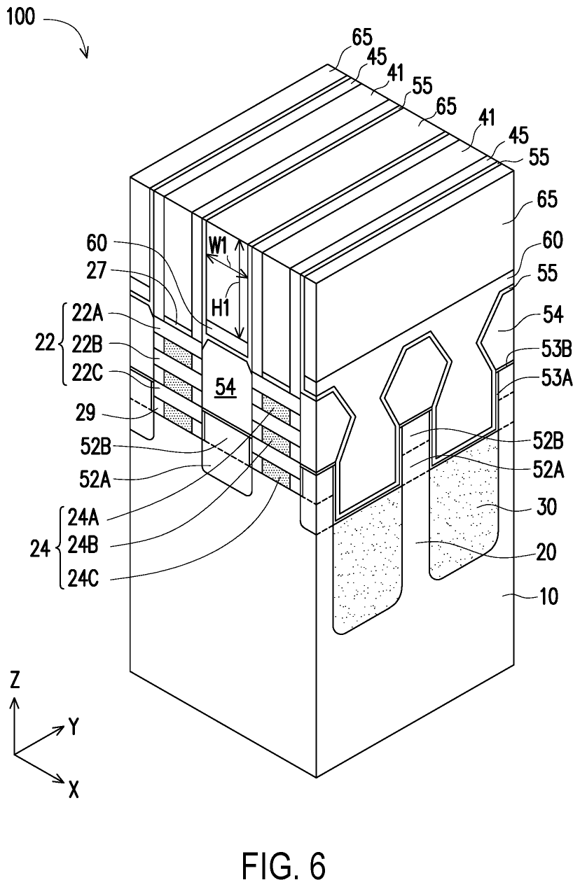

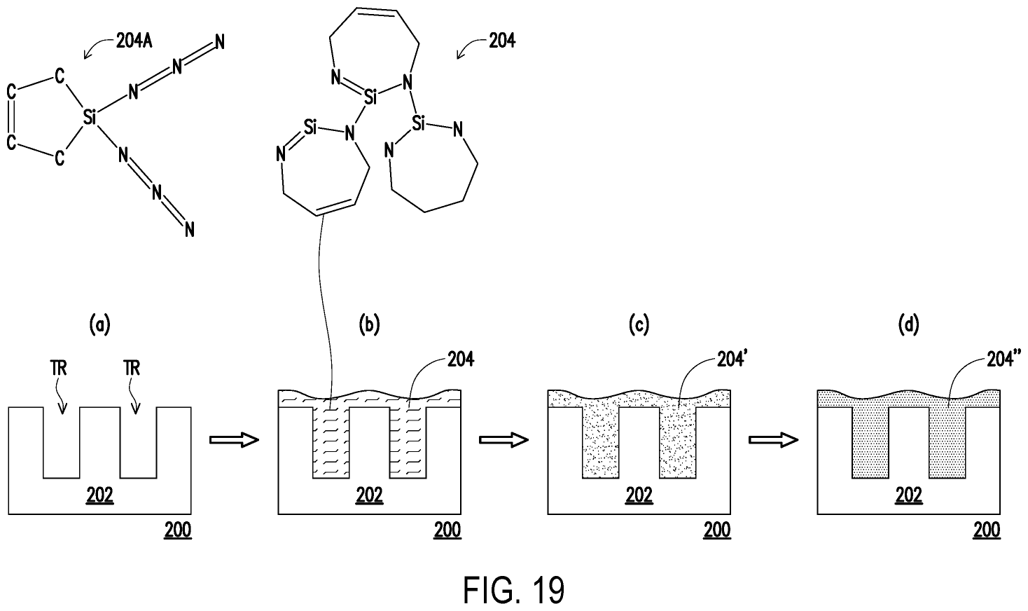

Thereafter, referring to FIG. 6, a gap-fill material is formed through a bottom-up gap filling deposition process, and the gap-fill material formed through such deposition process covers the ILD layer 60 and fills up the trenches TR2. In some embodiments, the bottom-up gap filling deposition process is performed until the exposed top surfaces of the dummy gate layers 41, the spacers 45, the CESL 55, and the ILD layer 60 are fully covered. In certain embodiments of the present disclosure, the gap-fill material is or includes a crosslinked product (cured product) of silicon carbon nitride (SiCN) based oligomers. The bottom-up gap filling deposition process for forming the gap-fill material and filling the trenches TR2 with the gap-fill material will be described later with reference to FIG. 19. By using the above-mentioned bottom-up deposition process, the so-formed gap-fill material fully fills up the trenches TR2, and the gap-fill material filled in the trenches TR2 is void-free and seam-free. It is important to form the void-free and seam-free gap-fill material filled into the trenches because no slit or gap may be formed in the gap-fill material after planarized or polished and better insulation and/or isolation is provided in the subsequent processes.

After the deposition of the gap-fill material, a planarization process is performed to expose the dummy gate layers 41, the spacers 45, and the CESL 55. In one embodiment, the planarization process includes CMP or grinding process. After the CMP process, the remained gap-fill material in the trenches TR1 and over the ILD layer 60 form hard mask layers 65. In some embodiments, the hard mask layer 65 is used to protect the underlying ILD 60 from damage during a subsequent gate replacement process. As shown in FIG. 6, top surfaces of the dummy gate layers 41, the spacers 45, the CESL 55, and the hard mask layer 65 are coplanar with one another after the planarization process. In some embodiments, the hard mask layer 65 has a height H1 substantially equal to or greater than the etched-back vertical dimension of the ILD layer 60. In addition, the hard mask layer 65 has a width W1 substantially equal to a lateral distance between the CESLs 55 on adjacent dummy gate structures. In some other embodiments, a height to width ratio (H1/W1) of the hard mask layer 65 is no less than 3.

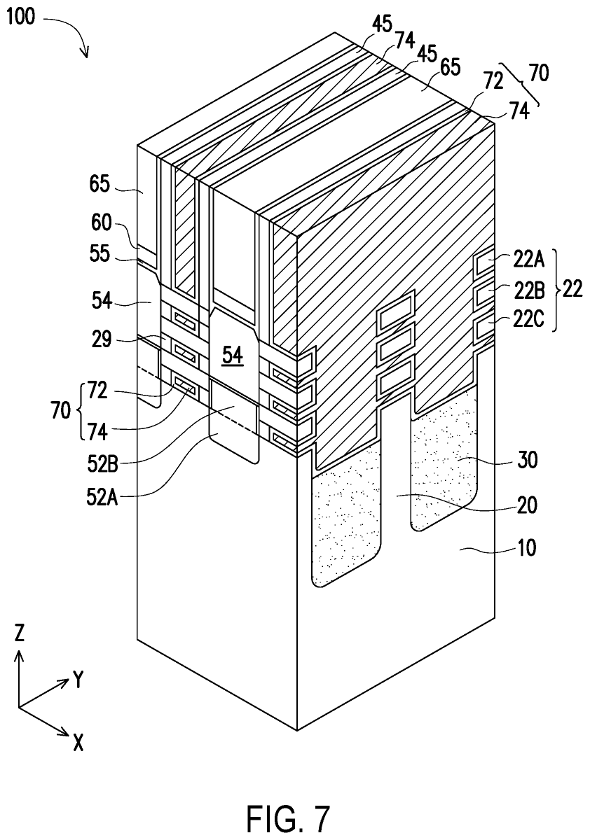

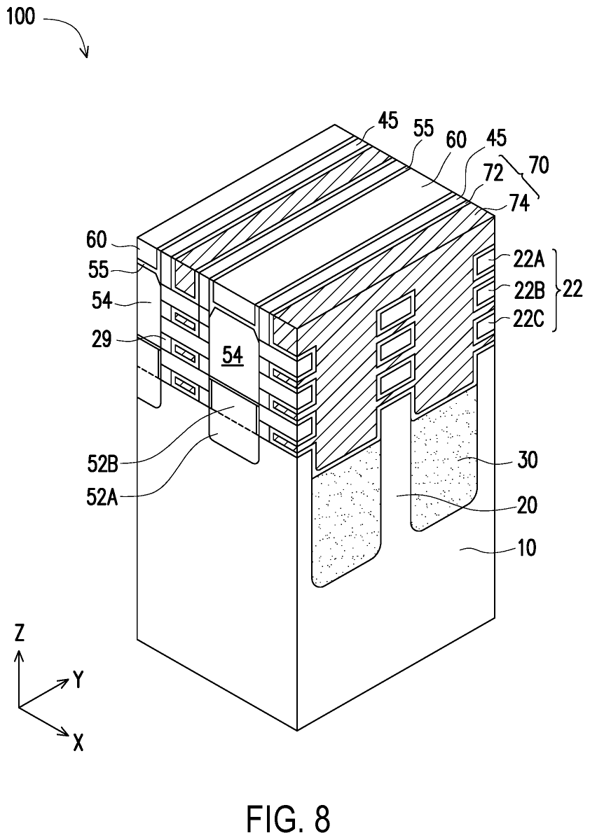

Referring to FIG. 7 and FIG. 8, a gate replacement process is performed to replace the dummy gate layers 41 with a gate structure 70. For the clarity of discussion, FIG. 7 thereafter shows perspective view of the semiconductor structure 100 in a different YZ cross-section. For example, the nanostructures 22, 24 are shown in YZ cross-section in FIGS. 7-15. The gate replacement process begins with removing the dummy gate layers 41. In some embodiments, the dummy gate layers 41 are removed using one or more suitable dry etching processes and/or wet etching processes. For example, in cases where the dummy gate layers 41 are polysilicon and the ILD layer 60 is silicon oxide, a wet etchant, such as a tetramethylammonium hydroxide (TMAH) solution is used to selectively remove the dummy gate layers 41 without removing the dielectric materials of the hard mask layers 65, the ILD layer 60, the CESL 55, the spacers 45, and the dielectric layer 27. In some embodiments, the source/drain structures 54 are protected by the hard mask layers 65, the ILD layer 60 and the CESL 55 during the removal of the dummy gate layers 41.

In some embodiments, the dielectric layer 27 conformally formed on the nanostructures 22, 24 is removed using plasma dry etching and/or wet etching, for example. In some embodiments, the removal of the dielectric layer 27 causes damages to the insulation material of the isolation regions 30, thereby partially recessing the isolation regions 30. The removal of the dummy gate layers 41 and the dielectric layer 27 together form trenches (not shown) exposing the nanostructures 22, 24, the isolation regions 30 and the outer sidewalls of the spacers 45.

In some embodiments, the second nanostructures 24A-24C are then removed from the trenches (not shown), while the first nanostructures 22A-22C are remained. In some embodiments, the removal of the second nanostructures 24A-24C results in multiple gaps formed between the first nanostructures 22A-22C connecting to the source/drain structures 54. Accordingly, each of the first nanostructures 22A-22C has surfaces (e.g., top surface and bottom surface) exposed by the gaps, and the exposed surfaces are opposite to each other and are perpendicular to the longitudinal direction (e.g., the Z-direction). In some embodiments, the exposed surfaces will be surrounded by a subsequently formed gate layer, and each of the first nanostructures 22A-22C forms a nanosheet channel of the nanosheet transistor. In some embodiments, the first nanostructures 22 may be referred to as nanostructure stacks each including a plurality of nanostructures (e.g., first nanostructures 22A-22C) stacked over one another.

In some embodiments, the second nanostructures 24A-24C are removed using any suitable selective removal process, such as a selective wet etching process and a selective dry etching process. After formation of the nanoshect channels (i.e., the first nanostructures 22A-22C), a gate dielectric layer 72 is conformally formed on surfaces exposed by the trenches and gaps. For example, the gate dielectric layer 72 is formed to wrap around each of the first nanostructures 22A-22C and to cover exposed surfaces of the isolation regions 30 and the fins 20 and the sidewalls of the spacers 45. In some embodiments, the gate dielectric layer 72 includes one or more layers of a dielectric material, such as silicon oxide, silicon nitride, high-K dielectric material, other suitable dielectric material, and/or a combination thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or a combination thereof. In one embodiment, the gate dielectric layer 72 is formed using a conformal deposition process, such as ALD to ensure that a gate dielectric layer of uniform thickness is formed around each of the first nanostructures 22A-22C.

In some embodiments, a gate layer 74 is formed on the gate dielectric layer 72 to surround a portion of each of the first nanostructures 22A-22C, and further fill the trenches and the gaps. For example, the gate layer 74 is deposited until top surfaces of the spacers 45, the CESL 55. the ILD layer 60, and the hard mask layers 65 are covered. In some embodiments, the gate layer 74 includes one or more layers of metallic materials, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, and/or any combinations thereof. In some embodiments, the gate layer 74 includes a conductive material, such as polysilicon. For example, the gate layer 74 may be formed by CVD, ALD, electro-plating, or other suitable deposition technique.

In some embodiments, as the gap-fill material of the hard mask 65 is void-free and seam-free, no metal penetration or diffusion occurs in the gap-fill material during the formation of the metallic gate layer of the gate replacement process. Hence, the gap-fill material of the hard mask 65 provides better masking effect or better protection for the underlying layer(s), thereby improving the device performance.

In some embodiments, a planarization process is performed on the semiconductor structure 100 shown in FIG. 7 until the ILD layer 60 is exposed, and the planarized structure is shown in FIG. 8. For example, the planarization process is performed using CMP or grinding process, and the hard mask layer 65 may be completely removed after the planarization process. In some embodiments, the remaining gate dielectric layer 72 and gate layer 74 are collectively referred to as a gate structure 70. In some embodiments, subsequent to the planarization process, top surfaces of the gate structures 70, the ILD layer 60, the CESL 55, and the spacers 45 are substantially coplanar with one another. As shown in FIG. 8, the gate structures 70 wraps around the nanostructures 22 and extends between the adjacent nanostructure stacks (e.g., each nanostructure stack including the nanostructures 22A-22C stacked over each other). In addition, the first nanostructures 22, the source/drain structures 54, and the gates structures 70 (including the gate dielectric layer 72 and the gate layer 74) may be collectively referred to as transistor structures.

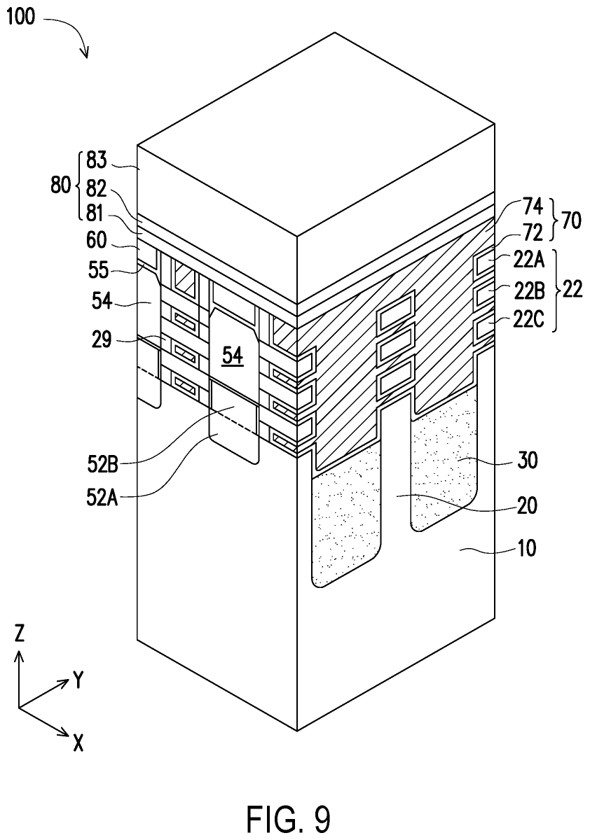

Referring to FIG. 9, a hard mask stack 80 including a first hard mask layer 81, a second hard mask layer 82, and a third hard mask layer 83 are sequentially formed over the semiconductor structure 100 shown in FIG. 8. For example, the hard mask stack 80 directly covers the gate structure 70, the ILD layer 60, the CESL 55, and the spacer 45. In some embodiments, the first and third hard mask layers 81, 83 include similar or substantially the same material, and the second hard mask layer 82 includes a material different from that of the first and third hard mask layers 81, 83. In one embodiment, the first and third hard mask layers 81, 83 are formed of silicon nitride and the second hard mask layer 82 is formed of silicon such as amorphous silicon (a-Si). Each of the hard mask layers of the hard mask stack 80 is deposited using a process such as CVD, PECVD, or ALD. In some embodiments, the hard mask layers 81, 82, and 83 are formed to have different thicknesses. For example, the third hard mask layer 83 is formed to be much thicker than the first and second mask layers 81, 82.

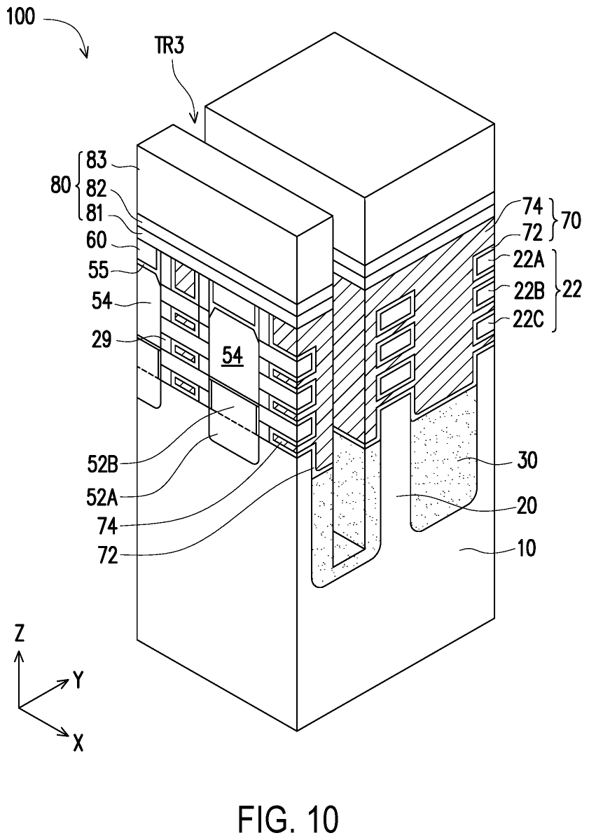

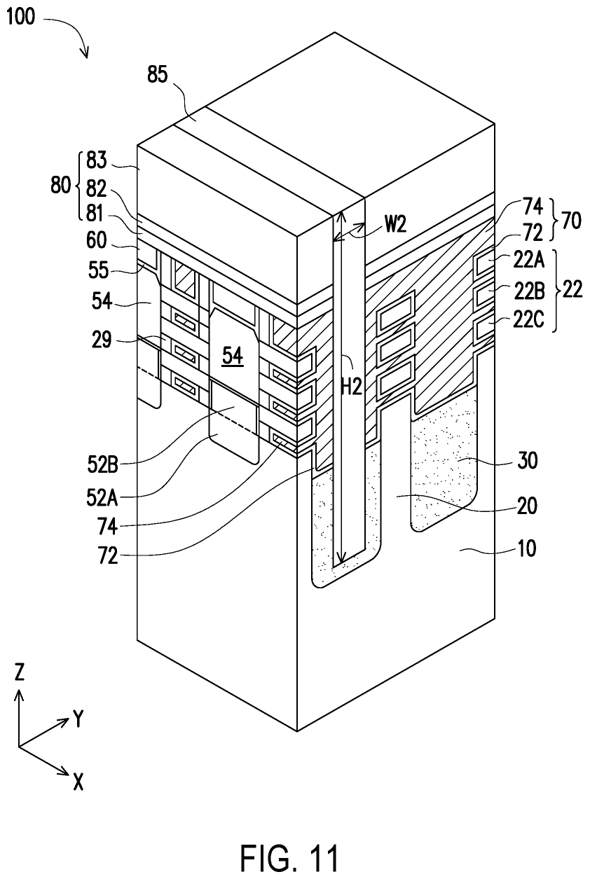

Referring to FIG. 10 and FIG. 11, a cut metal gate (CMG) process is performed. In some embodiments, the CMG process is used for forming isolation structure to separate/divide a continuous gate electrode (i.e., the gate structure 70) that spans over multiple nanostructure stacks into multiple segments. Such isolation structures may be referred to as gate cut features or CMG features, and each segment of the cut metal gate may serve as a gate electrode of an individual transistor.

In the exemplary embodiment, to form the gate cut feature, a gate cut trench (or opening) TR3 separating the gate structures 70 is first formed as shown in FIG. 10. The formation of the gate cut trench TR3 may include performing a patterning process using one or more photolithography processes and a subsequent anisotropic etching process. After the patterning process, the gate cut trench TR3 extends from the hard mask stack 80 and all the way through a major portion of the isolation regions 30. As shown in FIG. 10, isolation regions 30 are exposed at the bottom of the gate cut trench TR3. The gate cut trench TR3 may penetrate into or through the isolation regions 30, depending on product design. In some embodiments, the gate cut trench TR3 has a longitudinal direction in XY plane extending along the first direction (i.e., the X-direction) of the previously formed nanostructures 22, 24. In some other embodiments, the gate cut trench TR3 is formed with substantially vertical sidewalls. Alternatively, the gate cut trench TR3 may include tapered sidewalls. In some embodiments, a depth to width aspect ratio of the gate cut trench TR3 is 3 or more.

Thereafter, referring to FIG. 11 the gate cut trench TR3 is filled with a gap-fill material using a bottom-up gap filling deposition process followed by a planarization process. In some embodiments, the gap-fill material is or includes a crosslinked product (cured product) of silicon carbon nitride (SiCN) based oligomers. The bottom-up deposition process may be performed until a top surface of the hard mask layer 80 is covered with the gap-fill material. The bottom-up gap filling deposition process for filling in the gate cut trench TR3 is similar to the gap filling deposition process of the trench TR2, which will be described later with reference to FIG. 19. By using a bottom-up deposition process according to the embodiments of the present disclosure, the gate cut trench TR3 is completely filled up by the formed gap-fill material, and the gap filled material is formed without voids or seams in the gate cut trench TR3.

In some embodiments, the subsequent planarization process includes a CMP or grinding process. The remaining gap-fill material in the gate cut trench TR3 forms the gate cut feature 85. As shown in FIG. 11, top surfaces of the third hard mask layer 83 and the gate cut feature 85 are coplanar with each other after the planarization process. In some embodiments, the void-free or seam-free gate cut feature 85 can provide good isolation between gate electrodes of adjacent transistors. A height H2 of the gate cut feature 85 may be substantially equal to or less than that of the gate cut trench TR3, and a height to width ratio (H2/W2) of the gate cut feature 85 may be no less than 3. It should be noted that, the number and arrangement of the gate cut feature 85 shown in FIG. 11 is merely an example. Other arrangements and layouts are also possible and more than one gate cut feature 85 may also be formed.

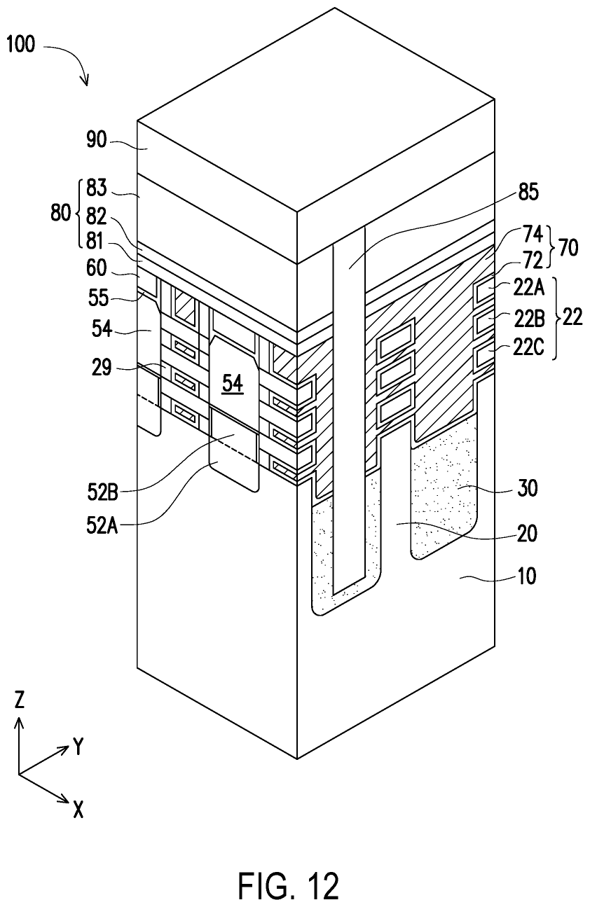

Referring to FIG. 12, in a subsequent step, a fourth hard mask layer 90 is formed over the hard mask stack 80 and the gate cut feature 85. In some embodiments, the fourth hard mask layer 90 is formed for a later patterning process that defines the active device region by forming isolation structures in the semiconductor structure 100. In some embodiments, the fourth hard mask layer 90 is formed of a material similar to that of the third hard mask layer 83. In one embodiment, the fourth hard mask layer 90 includes silicon nitride. In some embodiments, the fourth hard mask layer may be formed using a suitable deposition process such as CVD, PECVD, or ALD.

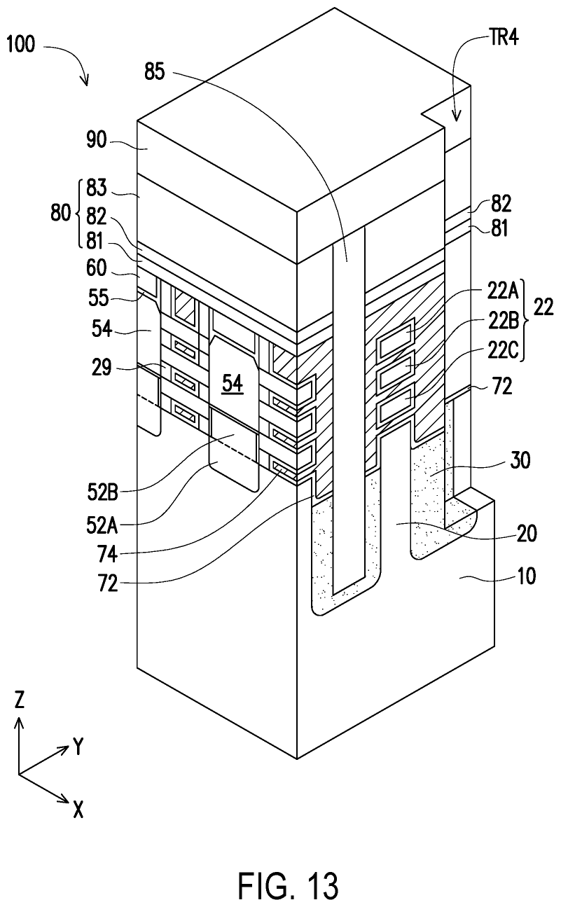

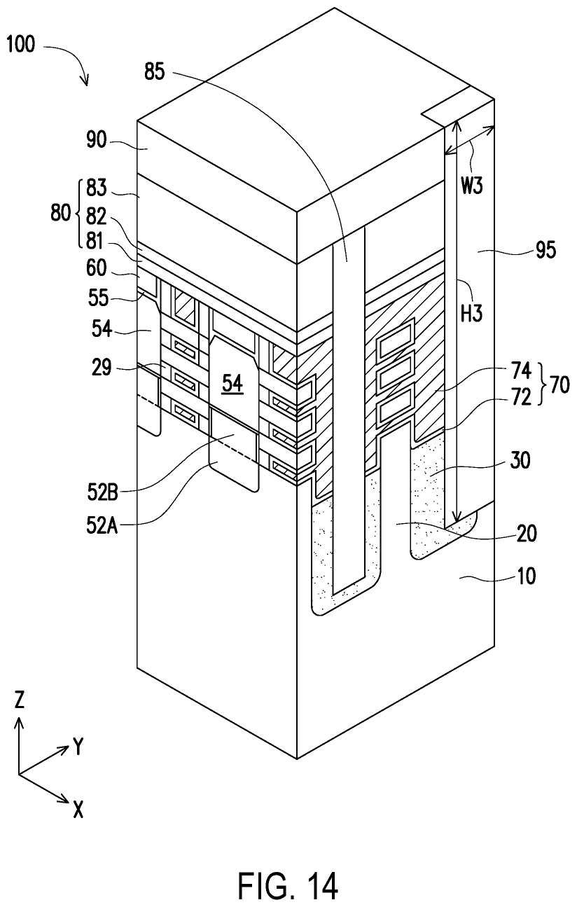

Referring to FIG. 13 and FIG. 14, a patterning process is performed and isolation structures 95 are formed. Generally, the isolation structure 95 is a dummy structure or a non-functional structure. In some embodiments, the isolation structure 95 is obtained by first forming a trench TR4, and then filling the trench TR4 with an insulation material. In some embodiments, the formation of the trench TR4 includes performing a patterning process using one or more photolithography processes and a subsequent anisotropic etching process to remove portions of the hard mask stack 80, portions of the gate structures 70, portions of the nanostructures 22, and portions of the fins 20. After the patterning process, the trench TR4 extends from the fourth hard mask layer 90, through the hard mask stack 80, and extends downward into the isolation region(s) 30. As illustrated in FIG. 13, a portion of the isolation region 30 is removed and the remained isolation region 30 is exposed by the trench TR3. The trench TR4 may penetrate into or through the isolation regions 30, depending on product design. In some embodiments, the trench TR4 has a longitudinal direction in XY plane extending along the second direction (i.e., the Y-direction) of the previously formed dummy gate structures 40. In some other embodiments, the trench TR4 is formed with substantially vertical sidewalls. Alternatively, the trench TR4 may include tapered sidewalls. In some embodiments, a depth to width aspect ratio of the trench TR4 is 3 or more.

In some embodiments, the trench TR4 is filled up with a gap-fill material (i.e. an insulating material) using a bottom-up deposition process followed by a planarization process. In some embodiments, the gap-fill material is or includes a crosslinked product (cured product) of silicon carbon nitride (SiCN) based oligomers. In some embodiments, the bottom-up deposition process is performed until a top surface of the fourth hard mask layer 90 is covered with the gap-fill material. The bottom-up gap filling deposition process for filling in the trench TR4 is similar to those processes for filling the trench TR2 and the gate cut trench TR3 which will be described later with reference to FIG. 19. By using a bottom-up deposition process according to the embodiments of the present disclosure, the trench TR4 is fully filled up with the gap-fill material, and the gap-fill material is formed without voids or seams in the trench TR4.

In some embodiments, the subsequent planarization process includes CMP or grinding process. The remained gap-fill material in the trench TR3 forms the isolation structure 95, which serves as a non-functional isolation structure. As shown in FIG. 14, top surfaces of the fourth hard mask layer 90 and the isolation structure 95 are coplanar with each other after the planarization process. In some embodiments, the void-free or seam-free isolation structure 95 can provide good isolation between adjacent cells. A height H3 of the isolation structure 95 may be substantially equal to or less than that of the trench TR3, and a height to width ratio (H3/W3) of the isolation structure 95 may be no less than 3. That is, the previously formed trench TR3 is, for example, an opening with a high aspect ratio. It should be noted that, the number and arrangement of the isolation structure 95 shown in FIG. 14 is merely an example. Other arrangements and layouts are also possible and more than one isolation structure 95 may also be formed.

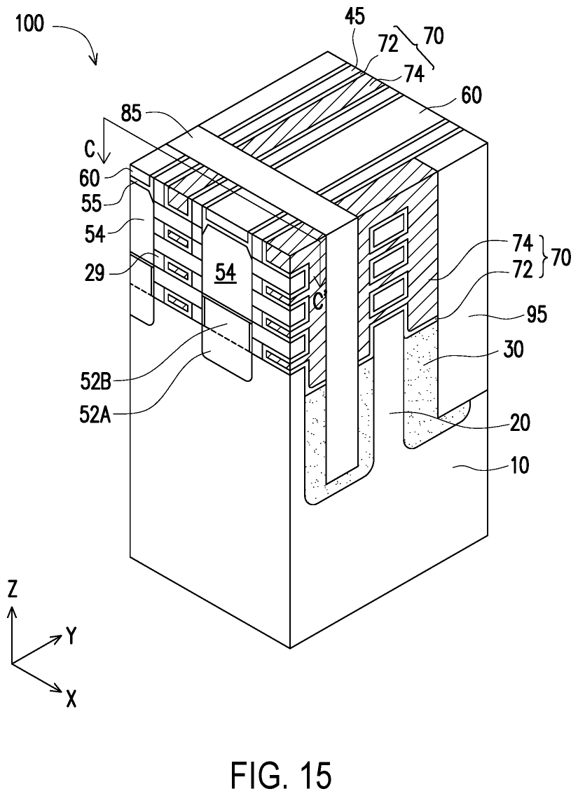

Referring to FIG. 15, a planarization process such as CMP or grinding process is performed on the front-side of the semiconductor structure 100 shown in FIG. 14 until the gate structure 70 is exposed. After the planarization process, top surfaces of the remaining portions of the isolation structure 95, the gate cut feature 85, the gate structure 70, the ILD layer 60, the CESL 55, and the spacers 42 are substantially coplanar to one another. In other words, with the bottoms of the trenches TR3 and TR4 at the same horizontal level, the isolation structure 95 and the gate cut feature 85 may have substantially same height.

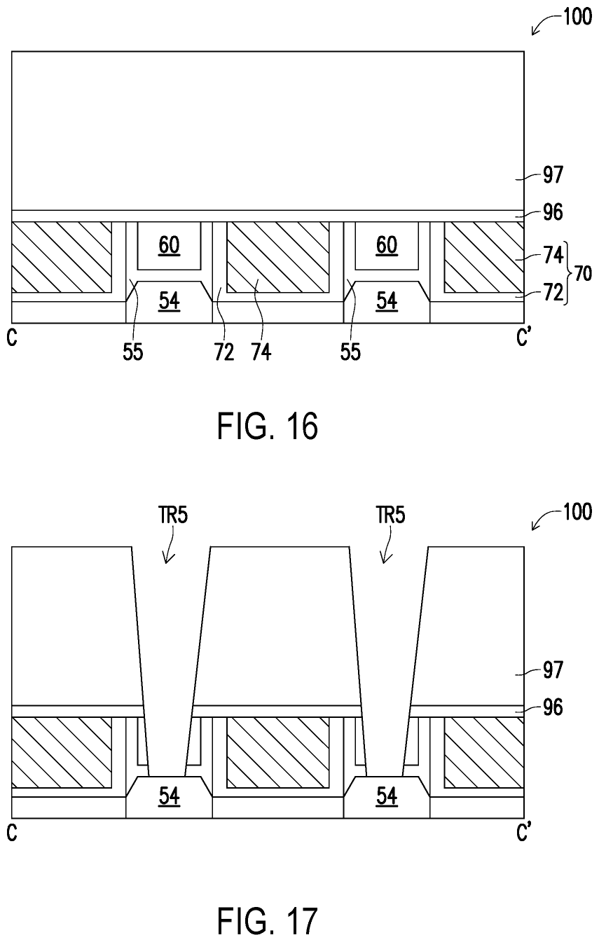

FIG. 16 to FIG. 18 illustrates the formation of contact structures CT1 to the source/drain structures 54. For the clarity of discussion, FIG. 16 to FIG. 18 illustrates subsequent steps in forming the semiconductor structure 100 from a cross-sectional view shown in FIG. 15 taken along the line C-C′. In FIG. 16 to FIG. 18, portions of the gate structure 70 and portions of the source/drain structures 54 are illustrated, while nanostructures 22 and other components located underneath are omitted for case of illustration. As illustrated in FIG. 16, after forming the isolation structure 95 and the gate cut feature 85 and performing the planarization process, an etch-stop layer (ESL) 96 and a dielectric layer 97 are formed on the gate structures 70, and formed on the ILD layer 60 and the CESL 55. In some embodiments, the ESL 96 includes silicon and nitrogen and/or carbon (for example, SiN, SiCN, SiCON, SiON, SiC, and/or SiCO) (and can thus be referred to as a silicon nitride layer). In some embodiments, the dielectric layer 97 includes a dielectric material including, for example, silicon oxide, silicon nitride, silicon oxynitride, tetraethyl orthosilicate (TEOS) oxide, PSG, BPSG, low-k dielectric material, other suitable dielectric material, or combinations thereof. In certain embodiments, the dielectric layer 97 and/or the ESL 96 are formed by a deposition process, such as CVD, PVD, ALD, other suitable methods, or combinations thereof.

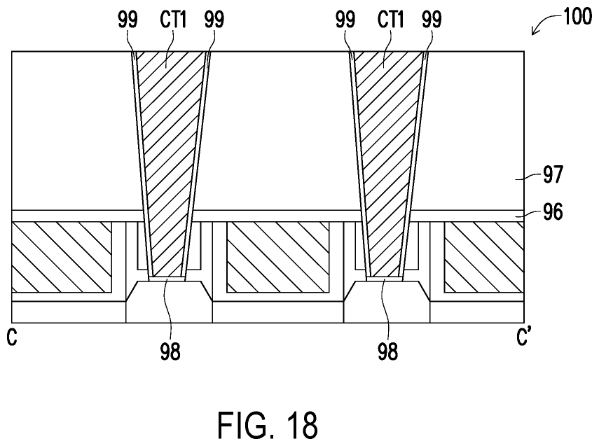

Referring to FIG. 17, a patterning process is performed to form trenches TR5 (or openings) in the dielectric layer 97, the ESL 96, the ILD layer 60 and the CESL 55. For example, the patterning process includes using one or more photolithography processes, and/or anisotropic etching processes. In some embodiments, after forming the trenches TR5 (or openings), a top surface of the source/drain structures 54 is revealed. Next, referring to FIG. 18, in some embodiments, a silicide layer 98 may be formed at a bottom of the trenches TR5 for reducing the resistance between the source/drain structures 54 and the subsequently formed contact structures CT1. For example, the silicide layer 98 includes nickel silicide (NiSi), cobalt silicide (CoSi), titanium silicide (TiSi), tungsten silicide (WSi), molybdenum silicide (MoSi), platinum silicide (PtSi), palladium silicide (PdSi) or the like.

As illustrated in FIG. 18, liner structures 99 are formed on sidewalls of the trenches TR5, and formed over the silicide layer 98. In some embodiments, the liner structures 99 are formed through a deposition process, such as an atomic layer deposition (ALD) process on sidewalls of the trenches TR5, whereby a material and process of forming the liner structures 99 will be described later with reference to FIG. 20 through FIG. 21. By using the material and process of the present disclosure for forming the liner structures 99, an ultrathin liner structure (<2 nm) that is free of pin holes or voids can be obtained.

Thereafter, contact structures CT1 may be formed in the trenches TR5 to fill up the trenches TR5. In some embodiments, the contact structures CT1 are formed between the liner structures 99, and are connected to the source/drain structures 54 through the silicide layer 98. The contact structures CT1 may include conductive materials such as cobalt (Co), tungsten (W), ruthenium (Ru), aluminum (Al), copper (Cu), or other suitable conductors, and be deposited by performing a suitable deposition process, such as CVD, PVD, ALD sputtering, e-beam evaporation, or any combination thereof. In some embodiments, a planarization process such as a CMP process, is performed to remove any excessive conductive materials of the contact structures CT1 formed over the dielectric layer 97. In certain embodiments, a top surface of the contact structures CT1 is leveled and coplanar with the top surface of the dielectric layer 97 and the top surface of the liner structures 99 after the planarization process.

Up to here, a semiconductor device of a semiconductor structure 100 is fabricated. The semiconductor device here generally refers to the layer formed over the substrate 10 as illustrated in FIG. 15 and FIG. 18. For example, the semiconductor device includes a plurality of transistors, and include the fins 20 and the nanostructures 22 functioned as channels, the isolation regions 30, the source/drain structures 54 formed aside the nanostructures 22, the gate structures 70, around the nanostructures, 22 the contact structures CT1 above the source/drain structures 54, dummy structures (i.e., non-functional structures) such as the gate cut feature 85 and the isolation structure 95, and dielectric layers formed therebetween.

FIG. 19 shows schematic cross-sectional views of various steps in a bottom-up a deposition process during the formation of a semiconductor structure 100 in accordance with some embodiments of the present disclosure. Referring to FIG. 19, a simplified semiconductor structure 200 is shown in each step (a)-(d) of the bottom-up deposition process. The simplified semiconductor structure 200 is very similar to the semiconductor structure 100, and a semiconductor device 202 is shown as a simplification of the semiconductor device of the semiconductor structure 100. For example, the semiconductor device 202 is fabricated over a substrate (not shown) using suitable processes including film deposition process, epitaxy process, thermal process, photolithography process, etching process, material filling process, and planarization process, among others.

For ease of understanding, the semiconductor structure 200 in FIG. 19 only shows trenches TR in the semiconductor device 202. In some embodiments, the trenches TR may represent the trenches TR2, TR3, TR4 as described respectively in FIG. 5, FIG. 10, and FIG. 13. In some embodiments, a depth of the trench TR ranges from about 15 nm to about 300 nm, and a width of the trench TR ranges from about 3 nm to about 150 nm. In other words, an aspect ratio (i.e., depth to width ratio) may be greater than or equal to 3. Although the trenches TR in FIG. 16 are shown with substantially vertical sidewalls; however, the trenches may be etched to have tapered sidewalls. A bottom-up gap filling deposition process is then performed to fill the high aspect ratio trenches TR (i.e., trenches TR2, TR3, TR4) with gap-fill material. In one embodiment, the gap-fill material filling the trenches TR is a crosslinked product (or cured product) of silicon carbon nitride (SiCN) based oligomers.

As shown in step (a), after the trenches TR are formed, a precursor 204A is used in a deposition process for forming the gap-fill material. In the exemplary embodiment, the precursor 204A is a precursor that undergoes a Curtius-type rearrangement process. In some embodiments, the precursor 204A used in the deposition process includes azidosilane, di-azidosilane or halide azidosilane. For example, the precursor is a compound selected from the group consisting of formula (1A) to formula (1C):

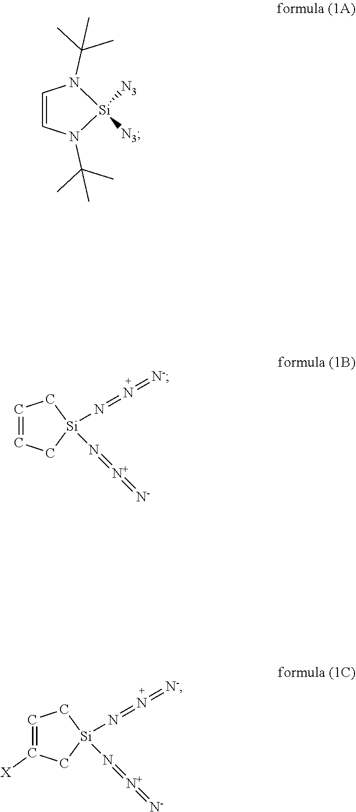

wherein, in formula (1C), X is a halogen selected from the group consisting of iodine, bromine and chlorine.

Referring to step (b) in FIG. 19, the bottom-up deposition process includes using the precursor 204A described above for performing a deposition process, such as a flowable CVD process to form oligomers 204 in the trenches TR. In some embodiments, when the precursor 204A used in the flowable CVD process is selected from the group consisting of formula (1A) to formula (1C) above, then the precursor 204A undergoes a Curtius-type rearrangement process to form oligomers 204 selected from the group consisting of formula (2A) to formula (2E) in the trenches TR, wherein the oligomers 204 are silicon carbon nitride (SiCN) based oligomers with 3 rings to 7 rings.

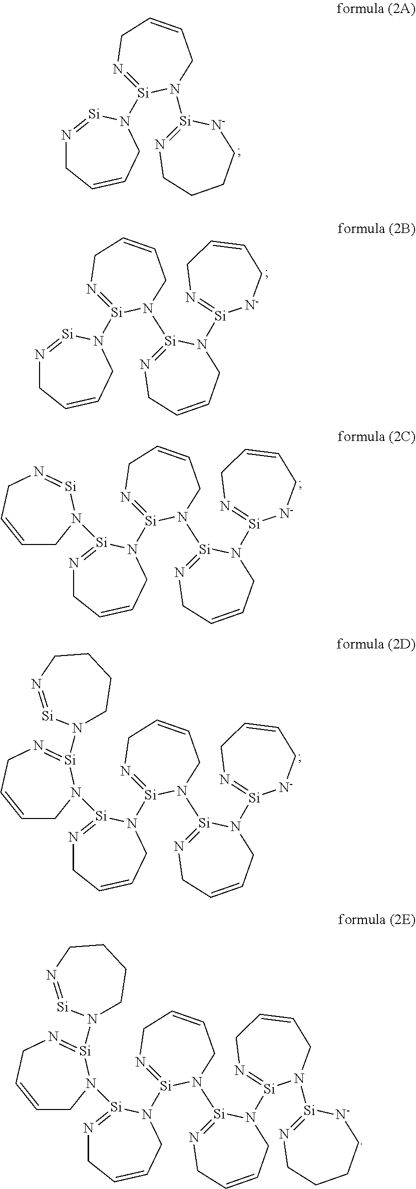

In step (b) of FIG. 19, a CVD tool (not specifically shown) may be used to introduce vapor phase precursors into the process chamber (i.e., CVD chamber) to react and form the oligomers 204 filling the trenches TR. In some embodiments, the precursors 204A may be introduced into the chamber via a carrier gas such as Helium (He). Furthermore, the flowable CVD may be performed at a suitable temperature ranging from about 300° C. to 500° C. (in particular, 300° C. to 450° C.) to promote the Curtius reaction, and performed under a pressure ranging from about a few millitorr (mTorr) to about 30 Torr. In the exemplary embodiment, the size of the oligomers 204 is tunable by controlling the temperature of performing flowable CVD. For example, oligomers 204 with three rings (formula (2A)) are formed at a relatively lower temperature (˜300° C.), while oligomers 204 with seven rings (formula (2E)) are formed at a relatively higher temperature (˜450° C.).

By implementing such bottom-up mechanism of the flowable CVD to fill or refill the trenches TR with a gap-fill material, and due to the formation of the oligomers 204 with a low sticking coefficient as the gap-fill material, the formation of voids or vertical seams can be avoided, thereby offering better isolation and improving device performance and yield. Compared to other deposition processes, the flowable CVD can be performed at a lower temperature with a lower thermal budget, which can effectively reduce the diffusion of the dopants within the semiconductor device. In addition, the gap filling process using the flowable CVD also prevents plasma damages to the under-layer(s), when compared with other plasma assisted deposition processes such as plasma enhanced CVD (PECVD) or plasma-enhanced ALD (PEALD).

In step (c) of FIG. 19, the deposited oligomers 204 is subjected to an UV curing process using a UV light with wavelength of about 100 nm to about 400 nm. In some embodiments, the UV curing is performed at a temperature ranging from about 0° C. to about 400° C. and under a pressure ranging from about a few mTorr to about 30 Torr. A diluted gas such as argon (Ar), helium (He), hydrogen (H₂), neon (Ne), krypton (Kr), and xenon (Xe) may be used during the UV curing. In one embodiment, a pure Ar environment is provided for the UV curing to minimize an out-gassing effect. In the exemplary embodiment, the oligomers 204 can be fully cured and crosslinked to form a cured product 204′ of the oligomers. For examples, the oligomers shown in formula (2A) to formula (2E) may be cured and crosslinked to form the cured product 204′.

In step (d) of FIG. 19, a nitrogen plasma treatment may be optionally performed to further densify the cured product 204′ of the oligomers to become the treated silicon carbon nitride-based film 204″. In some embodiments, the nitrogen plasma treatment injects nitrogen into the material, drives impurities out of the film, and increases nitrogen/silicon (N/Si) ratios of the cured product 204′. In some embodiments, the nitrogen plasma treatment includes a single-step process or a multi-step process. For example, microwave (MW), Electron Cyclotron Resonance (ECR), Capacitively Coupled Plasma (CCP), and Inductively Coupled Plasma (ICP) can be used for the nitrogen plasma treatment. The nitrogen source may be nitrogen ion (N, N₂), nitrogen radical (N*, N₂*), NH ion (NH, NH₂, NH₃), and/or NH radical (NH*, NH₂*, NH₃*). In some embodiment, a diluted gas such as Ar, He, H₂, Ne, Kr, and Xe may be used during the nitrogen plasma treatment.

In some embodiments, the MW plasma treatment is performed with a process temperature of about 200° C. to about 500° C. and a process pressure of about a few mTorr to about 5 Torr. In some embodiments, the ECR plasma treatment is performed with a process temperature of about 0° C. to about 200° C. and a process pressure of about a few mTorr to about 10 Torr. In some embodiments the ICP or CCP plasma treatment is applied with a process temperature of about 300° C. to about 700° C. and a process pressure of about a few mTorr to about 22 Torr.

FIG. 20 illustrates a possible reaction mechanism for forming liner structures in the formation of a semiconductor structure in accordance with some embodiments of the present disclosure. Referring to FIG. 20, a simplified semiconductor structure 200 is shown in each step (a)-(d) of a deposition of forming liner structures. The simplified semiconductor structure 200 is very similar to the semiconductor structure 100, and a semiconductor device 202 is shown as a simplification of the semiconductor device of the semiconductor structure 100. For example, the semiconductor device 202 is fabricated over a substrate (not shown) using suitable processes including film deposition process, epitaxy process, thermal process, photolithography process, etching process, material filling process, and planarization process, among others.

For ease of understanding, the semiconductor structure 200 in FIG. 20 only shows a surface of the semiconductor device 202. For example, the surface of the semiconductor device 202 may correspond to the sidewall surfaces in the trenches TR1, TR5 as described respectively in FIG. 2A, FIG. 2B and FIG. 17. As shown in step (a) of FIG. 20, after the trenches (e.g. trenches TR1, TR5) are formed, a precursor 206A is used in a deposition process for forming liner structures (e.g. liner structures 53A, 99). In the exemplary embodiment, the precursor 206A is a precursor that undergoes a Curtius-type rearrangement process. For example, the precursor 206A is halide azidosilane, wherein the halide azidosilane is a compound selected from the group consisting of formula (3A) to formula (3B):

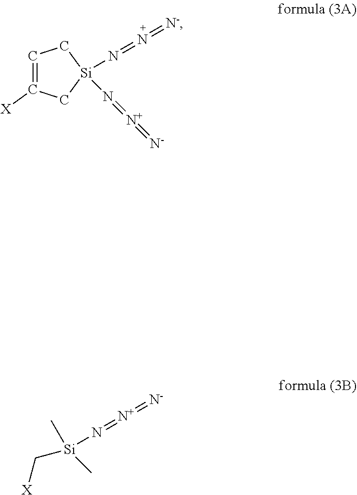

wherein, in formula (3A) and formula (3B), X is a halogen selected from the group consisting of iodine, bromine and chlorine.

In step (a) of FIG. 20, a precursor 206A having iodine as the halogen is used as an example. Furthermore, in the exemplary embodiment, the deposition process is an atomic layer deposition (ALD) process, whereby the steps (b)˜(c) illustrates a single ALD cycle. Referring to step (b) of FIG. 20, during the first ALD cycle, the precursor 206A is adsorbed onto the surface of the semiconductor device 202 (e.g. on sidewalls of the trenches TR1, TR5) by the decomposition of the halogen (e.g. 12 leaving group). In some embodiments, the halogen used in the precursor 206A is iodine, bromine and chlorine, while fluorine cannot be used in the ALD process as it cannot be decomposed at the process temperature of the ALD process. For example, the ALD process may be performed at a suitable temperature ranging from about 0° C. to about 300° C., and performed under a pressure ranging from about a few millitorr (mTorr) to about 30 Torr.

As illustrated in step (b′) and step (c), the adsorbed precursor 206A is subjected to an UV curing process during the ALD cycle using a UV light with wavelength of about 100 nm to about 400 nm. In some embodiments, the UV curing is performed at a temperature ranging from about 0° C. to about 400° C. and under a pressure ranging from about a few mTorr to about 30 Torr. A diluted gas such as argon (Ar), helium (He), hydrogen (H₂), neon (Ne), krypton (Kr), and xenon (Xe) may be used during the UV curing. In some embodiments, the UV curing process allows the precursor 206A to undergo a Curtius-type rearrangement process, so that the azides on the precursor 206A will rearrange to form an unstable intermediate 2061 (step (b′), and further form a cross-linked silicon carbon nitride (SiCN) film 206 (e.g. N₂ and C₃H₆ as leaving groups).

As shown in step (d), in a subsequent ALD cycle, further precursors 208A will react and connect to the NH terminal of the SiCN film 206 formed in the first ALD cycle. Thereafter, the steps (b)˜(c) may be repeated by performing the UV curing process to promote further film growth. The ALD cycles may be repeated until a liner structure having the desired thickness is formed.

In the exemplary embodiment, by implementing such an UV-assisted ALD process to form the liner structures (e.g. liner structures 53A, 99), the formed liner structures may have a thickness of 2 nm or less, and may be free of pin-holes or seams. As compared to conventional ALD process where precursors are adsorbed only at certain nucleation sites, the present disclosure uses halide azidosilane precursors for ALD, which can have a surface saturating property. In other words, instead of growing island-like films from the certain nucleation sites, the precursors used in the present disclosure may be saturated on the growing surface (surface of semiconductor device 202). As such, pin-holes or seams which are induced by island growth of precursors in the ALD process can be prevented when forming the liner structures.

FIG. 21 illustrates a possible reaction mechanism for forming liner structures in the formation of a semiconductor structure in accordance with some other embodiments of the present disclosure. The method illustrated in FIG. 21 is similar to the method illustrated in FIG. 20. Thus, the same reference numerals are used to refer to the same or liked parts, and its detailed description will be omitted herein. The difference between the embodiments is in the use of the precursors 206A, 208A. As illustrated in FIG. 20, a halide azidosilane having two azide terminals is used as the precursors 206A, 208A. However, the disclosure is not limited thereto. For example, referring to FIG. 21, a halide azidosilane having a single azide terminal is used as the precursors 206A, 208A.

As illustrated in steps (a)˜(b) of FIG. 21, the precursor 206A with a single azide terminal is adsorbed onto the surface of the semiconductor device 202 (e.g. on sidewalls of the trenches TR1, TR5) by the decomposition of the halogen in the first ALD cycle. In the first ALD cycle, the adsorbed precursor 206A is subjected to an UV curing process during the ALD cycle using a UV light with the same wavelength and temperatures described above. As such, the adsorbed precursor 206A may rearrange and crosslink to directly form a silicon carbon nitride (SiCN) film 206 shown in step (c). As shown in step (d), in a subsequent ALD cycle, further precursors 208A will react and connect to the N—CH₃ terminal of the SiCN film 206 formed in the first ALD cycle. Thereafter, the steps (b)˜(c) may be repeated by performing the UV curing process to promote further film growth. The ALD cycles may be repeated until a liner structure having the desired thickness is formed. From the disclosure above, it is clear that the precursor 206A used is not particularly limited as long as it includes a halogen (Cl, Br, or I) with high electronegativity and low decomposition energy for adsorption onto the growing surface, and include at least one azide terminal so that the precursor 206 can undergo the Curtius-type rearrangement process.

In the exemplary embodiment, by implementing such an UV-assisted ALD process to form the liner structures (e.g. liner structures 53A, 99), the formed liner structures may have a thickness of 2 nm or less, and may be free of pin-holes or seams.

In the above embodiments, in the method of forming a semiconductor structure, a precursor used in a flowable chemical vapor deposition process of forming a gap-fill material and a precursor used in the atomic layer deposition process of forming a liner structure undergoes a Curtius-type rearrangement process. As such, the formed gap-fill material is void-free and seam-free, and the formed liner structure is also free of pin-holes or scams.

In accordance with some embodiments of the present disclosure, a method for forming a semiconductor structure includes the following steps. A semiconductor device is formed over a substrate. A trench is formed in the semiconductor device. The trench is filled with a gap-fill material using a deposition process, wherein a precursor used in the deposition process includes azidosilane, di-azidosilane or halide azidosilane.

In accordance with some other embodiments of the present disclosure, a method for forming a semiconductor structure includes the following steps. A semiconductor device is formed over a substrate, wherein the semiconductor device includes a plurality of nanostructures, source/drain structures aside the plurality of nanostructures, gate structures around the plurality of nanostructures, and contact structures above the source/drain structures. The semiconductor device is patterned to form a trench, and the trench is filled with a gap-fill material using a flowable chemical vapor deposition process. The semiconductor device is patterned to form a second trench, and liner structures are formed on sidewalls of the second trench using an atomic layer deposition process. A precursor used in the flowable chemical vapor deposition process and a precursor used in the atomic layer deposition process undergoes a Curtius-type rearrangement process.

In accordance with yet another embodiment of the present disclosure, a semiconductor structure includes a plurality of transistors. The transistors include a plurality of nanostructures, source/drain structures located aside the nanostructures, contact structures above the source/drain structures, and a gap-fill material located aside the gate structure above the source/drain structures. The gap-fill material is a cured product of an oligomer selected from the group consisting of formula (2A) to formula (2E):

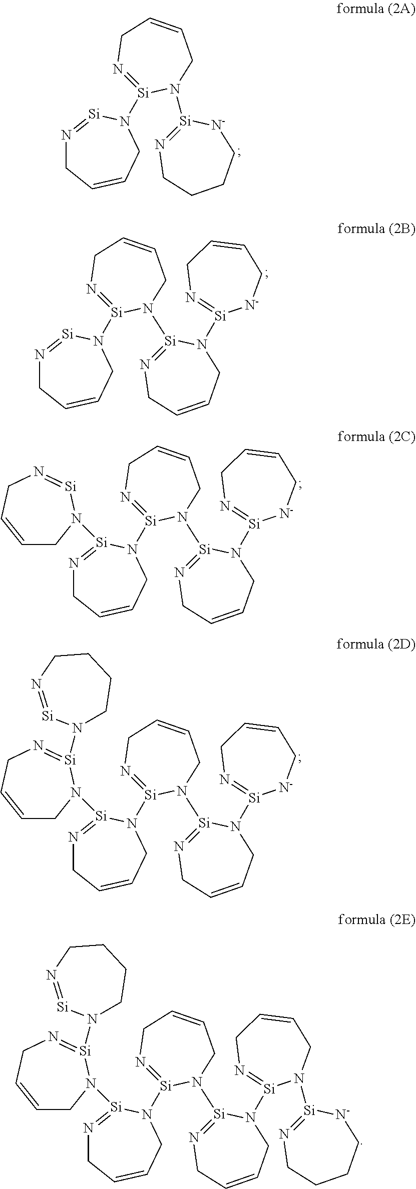

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a semiconductor device over a substrate;
forming a trench in the semiconductor device; and
filling the trench with a gap-fill material using a deposition process, wherein a precursor used in the deposition process comprises azidosilane, di-azidosilane or halide azidosilane.

2. The method according to claim 1, wherein the precursor is a compound selected from the group consisting of formula (1A) to formula (1C): 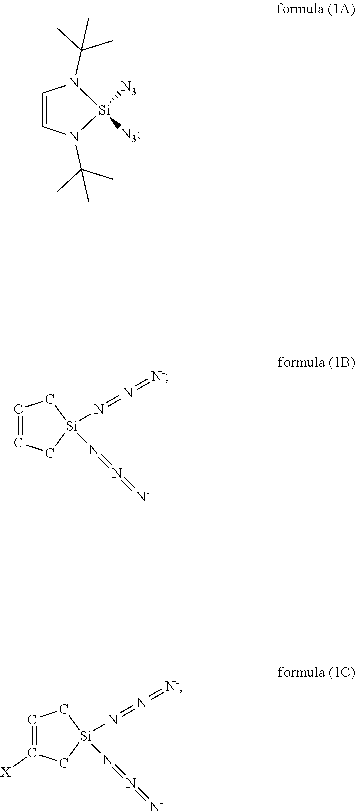
wherein, in formula (1C), X is a halogen selected from the group consisting of iodine, bromine and chlorine.

3. The method according to claim 1, wherein the deposition process is a flowable chemical vapor deposition process performed at a temperature range from 300° C. to 500° C.

4. The method according to claim 1, wherein after performing the flowable chemical vapor deposition process, the precursor undergoes a Curtius-type rearrangement process to form an oligomer selected from the group consisting of formula (2A) to formula (2E):

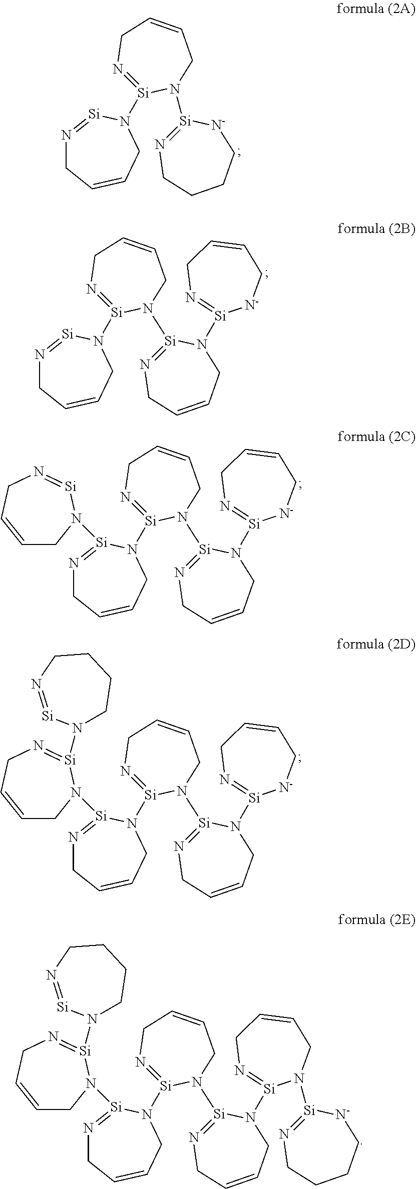

5. The method according to claim 1, further comprising:
performing a curing process to the gap-fill material after the deposition process with a UV light to form a cured gap-fill material, wherein the curing process is performed at a temperature range from 0° C. to 400° C.

6. The method according to claim 5, further comprising performing a nitrogen plasma treatment to the cured gap-fill material after the curing process, wherein the nitrogen plasma treatment includes a microwave plasma process, an electron cyclotron resonance plasma process, a capacitively coupled plasma process, or an inductively coupled plasma process.

7. The method according to claim 1, wherein a width of the trench is in a range of 3 nm to 150 nm, and a depth of the trench is in a range of 15 nm to 300 nm.

8. The method according to claim 1, further comprising:
forming a second trench in the semiconductor device; and
forming liner structures on sidewalls of the second trench using an atomic layer deposition process, wherein a precursor used in the atomic layer deposition process is halide azidosilane.

9. A method of forming a semiconductor structure, comprising:
forming a semiconductor device over a substrate, the semiconductor device comprising a plurality of nanostructures, source/drain structures aside the plurality of nanostructures, gate structures around the plurality of nanostructures, and contact structures above the source/drain structures;
patterning the semiconductor device to form a trench, and filling the trench with a gap-fill material using a flowable chemical vapor deposition process; and
patterning the semiconductor device to form a second trench, and forming liner structures on sidewalls of the second trench using an atomic layer deposition process, wherein
a precursor used in the flowable chemical vapor deposition process and a precursor used in the atomic layer deposition process undergoes a Curtius-type rearrangement process.

10. The method according to claim 9, wherein the liner structures are formed with a thickness of less than 2 nm.

11. The method according to claim 9, wherein the precursor used in the atomic layer deposition process is a compound selected from the group consisting of formula (3A) to formula (3B): 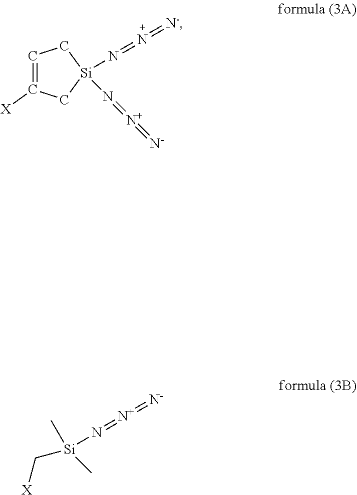
wherein, in formula (3A) and formula (3B), X is a halogen selected from the group consisting of iodine, bromine and chlorine.

12. The method according to claim 9, wherein the precursor used in the flowable chemical vapor deposition process is a compound selected from the group consisting of formula (1A) to formula (1C): 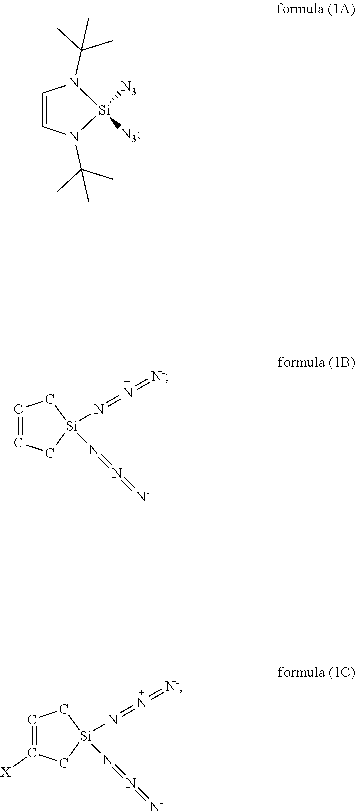
wherein, in formula (1C), X is a halogen selected from the group consisting of iodine, bromine and chlorine.

13. The method according to claim 9, wherein a depth to width aspect ratio of the trench is 3 or more.

14. The method according to claim 9, wherein the atomic layer deposition process is performed at a temperature range from 0° C. to 300° C.

15. The method according to claim 9, wherein the flowable chemical vapor deposition process is performed at a temperature range from 300° C. to 450° C.

16. The method according to claim 9, wherein the precursor in the flowable chemical vapor deposition process undergoes the Curtius-type rearrangement process to form an oligomer selected from the group consisting of formula (2A) to formula (2E):

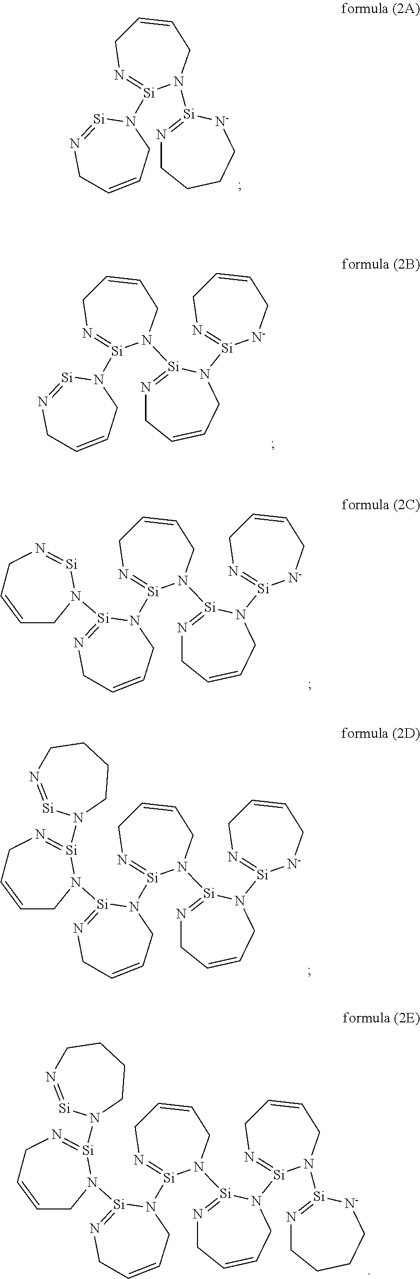

17. The method according to claim 9, further comprising:
performing a curing process to the gap-fill material after the flowable chemical vapor deposition process with a UV light to form a cured gap-fill material, and
performing a curing process in each atomic layer deposition cycle in the atomic layer deposition process,
wherein the curing process after the flowable chemical vapor deposition process and the curing process in each atomic layer deposition cycle in the atomic layer deposition process are performed at a temperature range from 0° C. to 400° C.

18. A semiconductor structure, comprising:
a plurality of transistors, wherein the plurality of transistors comprises:
a plurality of nanostructures;
source/drain structures located aside the nanostructures;
gate structure located around the plurality of nanostructures;
contact structures above the source/drain structures; and
a gap-fill material located aside the gate structure above the source/drain structures, wherein the gap-fill material is a cured product of an oligomer selected from the group consisting of formula (2A) to formula (2E):

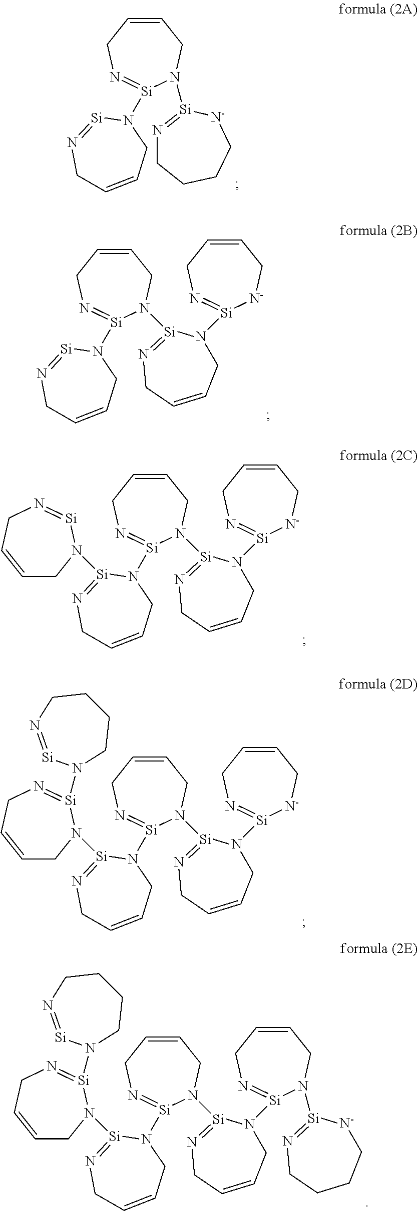

19. The semiconductor structure according to claim 18, further comprising a gate cut feature, wherein the gate cut feature is made of a material that is the cured product of the oligomer selected from the group consisting of formula (2A) to formula (2E).

20. The semiconductor structure according to claim 18, further comprising liner structures located on two sides of the contact structures, wherein the liner structures have a thickness of 2 nm or less, and is free of pin-holes or seams.
